(19) United States
(12) Patent Application Publication
(10) Pub. No.: US 2010/0096610 A1
(43) Pub. Date: Apr. 22, 2010

(54) PHASE-CHANGE MATERIAL MEMORY CELL

(76) Inventors: Hsingya A. Wang, San Jose, CA (US); Daniel R. Shepard, North Hampton, NH (US); Mac D. Apodaca, San Jose, CA (US); Ailian Zhao, Boxborough, MA (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/581,555

(22) Filed: Oct. 19, 2009

Related U.S. Application Data
(60) Provisional application No. 61/106,420, filed on Oct. 17, 2008.

(51) Int. Cl. H01L 47/00; H01L 21/06

(52) U.S. Cl. 257/2; 438/482; 257/E47.001; 257/42; 438/102; 257/E29.087; 257/E21.068

(57) ABSTRACT

A memory cell includes a current-steering device, a phase-change material disposed thereover, and a heating element and/or a cooling element.

### CROSS-REFERENCE TO RELATED APPLICATION

This application claims priority to and the benefit of, and incorporates herein by reference in its entirety, U.S. Provisional Patent Application No. 61/106,420, which was filed on Oct. 17, 2008.

### TECHNICAL FIELD

In various embodiments, the present invention relates to phase-change memory cells, and more particularly to the formation of heating and cooling elements in conjunction with a phase-change memory cell.

### BACKGROUND

Phase-change memory cells store information via changes in their resistivity characteristics. This is accomplished by, e.g., melting a phase-change material (PCM) such as Ge₂Sb₂Te₅ (GST), and then either rapidly cooling the material so as to leave that material in an amorphous, high-resistive state or slowly cooling the material so as to leave it in a crystalline, low-resistive state. Each material state corresponds to a different binary (zero or one) data value.

### SUMMARY

Embodiments of the present invention include methods for forming a phase-change memory cell for improved heating and cooling by forming an integral heating element and an integral cooling element. The heating mechanism may be implemented by implanting one or more elemental species in the material on which the PCM is positioned, which may be combined with a technique for confining the PCM to a smaller volume in the area of heating. The cooling mechanism may be implemented by minimizing the volume of the PCM to be cooled and providing a metal (e.g., tungsten) heat sink on top that also acts as an etch stop during formation of the upper contact.

In an aspect, embodiments of the invention feature a memory cell including or consisting essentially of a current-steering device, a phase-change material disposed over the current-steering device, and, disposed between the current-steering device and the phase-change material, an element for increasing heat transfer to the phase-change material upon application of a voltage to the memory cell. The current-steering device, the phase-change material, and the element cooperate to store data. Application of a voltage across the current-steering device results in heating of the phase-change material, and, depending on its cooling rate, the phase-change material acquires either a polycrystalline or an amorphous material state, each material state corresponding to a different binary (zero or one) data value.

The element may include or consist essentially of a layer having a resistance larger than the resistance of at least a portion of the current-steering device. The element may include one or more implanted elemental species, e.g., oxygen, nitrogen, and/or germanium. The current-steering device may include or consist essentially of a diode. The phase-change material may include or consist essentially of an alloy of germanium, antimony, and tellurium.

In another aspect, embodiments of the invention feature a method of forming a memory cell. A current-steering device is provided, as is a phase-change material thereover. An element for increasing heat transfer to the phase-change material upon application of a voltage to the memory cell is provided between the current-steering device and the phase-change material. The element may be provided by ion implantation of at least one elemental species. The elemental species may include or consist essentially of oxygen, nitrogen, and/or germanium.

In yet another aspect, embodiments of the invention feature a memory cell including or consisting essentially of a current-steering device, a cooling element disposed over the current-steering device, and a phase-change material disposed over the current-steering device and around at least a portion of the cooling element. The cooling element may include or consist essentially of a material having a higher thermal conductivity than the thermal conductivity of the phase-change material. The cooling element may include or consist essentially of a non-phase-change material, e.g., tungsten or diamond.

In a further aspect, embodiments of the invention feature a method of forming a memory cell. A current-steering device is provided. A volume of phase-change material disposed around a core region is provided over the current-steering device, and a cooling element is provided within the core region. The cooling element may include or consist essentially of a material having a higher thermal conductivity than the thermal conductivity of the phase-change material. The cooling element may include or consist essentially of a non-phase-change material, e.g., tungsten or diamond.

In another aspect, embodiments of the invention feature a memory cell including or consisting essentially of a current-steering device, a first phase-change material disposed over the current-steering device, a first breakdown layer disposed between the current-steering device and the first phase-change material, a second phase-change material disposed over the first phase-change material, and a second breakdown layer disposed between the first phase-change material and the second phase-change material. The first and/or the second breakdown layer may include or consist essentially of a dielectric material. The first and/or the second breakdown layer may include a breach therethrough. The first and second phase-change materials may be different.

In yet another aspect, embodiments of the invention feature a method of forming a memory cell. A current-steering device is provided, as is a first phase-change material thereover. A first breakdown layer is provided between the current-steering device and the first phase-change material. A second phase-change material is provided over the first phase-change material, and a second breakdown layer is provided between the first phase-change material and the second phase-change material. A first breach may be formed in the first breakdown layer by applying a voltage across the first breakdown layer. A second breach may be formed in the second breakdown layer by applying a voltage across the second breakdown layer.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawing, in which:

FIG. 1 illustrates a PCM memory cell according to embodiments of the present invention;

FIG. 2 illustrates a PCM memory cell according to embodiments of the present invention in which the heating within the PCM material is further constrained;

FIG. 3 illustrates a PCM memory cell according to embodiments of the present invention in which the heating within the PCM material is further constrained following initial breakdown of the lower breakdown layer; and

FIG. 4 illustrates a PCM memory cell according to embodiments of the present invention in which the heating within the PCM material is further constrained following secondary breakdown of the upper breakdown layer.

### DETAILED DESCRIPTION

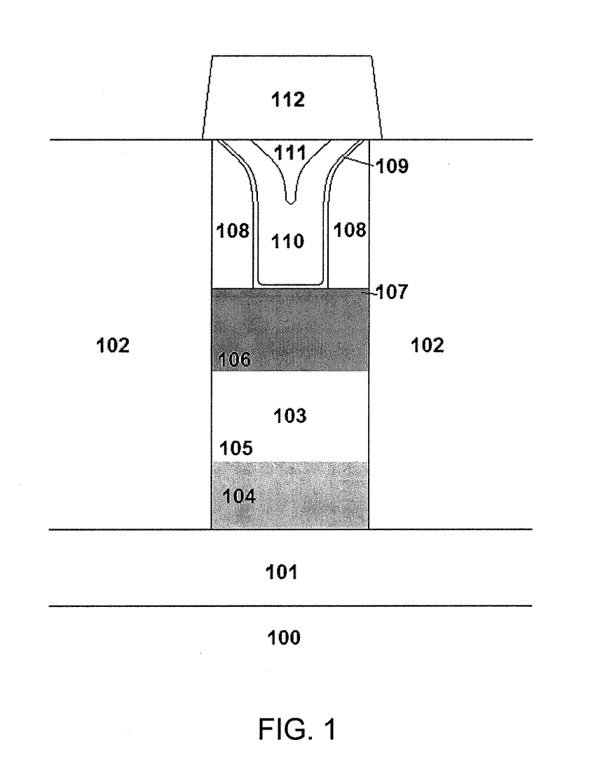

The process for fabricating deposited-material diodes on a silicon substrate is well known to those skilled in the art. Generally speaking and referencing FIG. 1, substrate 100 may be patterned with conductive rows 101 with a damascene process (or by patterning and etching) on top of which a current-steering device such as a diode 103 is fabricated. This diode 103 may be formed by depositing polysilicon that may be doped in situ or implanted; in one embodiment, N+ polysilicon 104 is deposited, followed by undoped polysilicon 105, the top portion of which is then implanted with p-type dopants to form p-type region 106. The stack may be then patterned and etched into a pillar shape wherever a diode is desired on row 101 or other bottom conductors (not shown). In the present examplary description, we assume the pillars are approximately 90 nm across, although other sizes and geometries are within the scope of the present invention. The resulting pillars may be blanket-filled around with a dielectric material 102 such as silicon oxide (SiO₂), and this may be polished to expose the tops of the polysilicon pillars. Next, about 80 nm of the polysilicon may be etched back by an etchant that is selective to remove the polysilicon as opposed to the dielectric material 102 (many etches are known to those skilled in the art that will etch polysilicon faster than SiO₂) leaving a “cup” on top of the diode. Note that the thickness of the p-type region 106 may allow for the partial removal of this layer to allow p⁺ polysilicon to remain following cup formation. The polysilicon stack may be annealed, at any point after any the implant steps through cup formation, to improve the conductivity of the polysilicon and to activate the dopant materials as is understood by those skilled in the art.

An approximately 50 Angstrom (Å) barrier liner layer of titanium (Ti) followed by approximately 100 Å of titanium nitride (TiN) may be deposited followed by an approximately 20-second rapid thermal anneal (RTA) at approximately 670° C. to form a metal-semiconductor alloy (e.g., a silicide). Tungsten (and/or any one or more other metals) contact material may be deposited over substrate 100, which may then be polished (e.g., by chemical-mechanical polishing (CMP)) to leave the cups filled with metal contact plugs. At this point, those diodes on which the phase-change cells are not to be formed may be patterned and masked such that the tungsten may be etched away (e.g., by peroxide wet etch which will stop on the TiN liner) above the diodes that will receive PCM material.

In one embodiment, dielectric layer 108 (i.e., a layer including or consisting essentially of a dielectric material such as silicon nitride) is next deposited conformally to build a sidewall spacer about 28 nm thick. This may be then etched back to remove the dielectric layer 108 on the wafer surface and at the bottom of the cups to leave the sidewall spacer in place (this is well understood by those skilled in the art, particularly by those skilled in the art of MOS transistor gate formation for those gates formed with sidewall spacers). Next, a breakdown layer 109 (i.e., a layer including or consisting essentially of a dielectric material such as SiO₂) may be deposited either by atomic layer deposition (ALD) or by sputtering (or other deposition techniques). The cup may then be filled by a blanket deposition (e.g., by sputtering) of the PCM material 110 (e.g., a layer including or consisting essentially of GST) and this film may be polished (e.g., by CMP with a tungsten polish) to remove all of the PCM material 110 except that within the cups. A top contact 112 may be formed by depositing, e.g., a thin layer of amorphous carbon as a barrier layer to the GST in the cups followed by top metal deposition, which is then patterned and etched to remove exposed top metal (and exposed amorphous carbon).

In one embodiment of the present invention, a heating element is added to the memory cell. To form a heating element to contact the PCM, a shallow I² implant 107 of an elemental species such as oxygen, nitrogen, and/or germanium may be performed to increase the resistance at the diode-PCM junction; that is to say just at the top of the diode 103 where it is closest to the PCM 110. In this way, the PCM may be heated more effectively when the storage location is to be altered (i.e., data is to be written).

In another embodiment of the present invention, an improved cooling element is added to the memory cell. At the point of GST deposition, the GST film may be deposited conformally, but this film may be made thin so as to not fill the volume of the cups. The remainder of the cup volume may be filled with a material 111 that is known to be a good conductor of heat. When the GST film is polished, a center core of the heat-conductive material 111 may remain in the center of the cup surrounded by the GST layer. In this way, heat from the GST volume may be better drawn away and into the top contact 112 where it will be dissipated. This non-phase-change heat-conductive material may include or consist essentially of tungsten, another metal, a dielectric, or an insulator such as diamond, e.g., chemical-vapor deposited (CVD) diamond (in this latter case, the current path will be through the PCM material sidewalls to the top conductor). In another embodiment, the core 111 is a conductor of higher resistivity and thereby helps the forming of the double BDL-confined GST regions. Furthermore, by reducing the volume of the GST material in this way, the heating, when it occurs, may be concentrated in a smaller volume of GST material, limiting the volume of material that experiences the phase change. Limiting the volume of the PCM in this way may increase its switching speed.

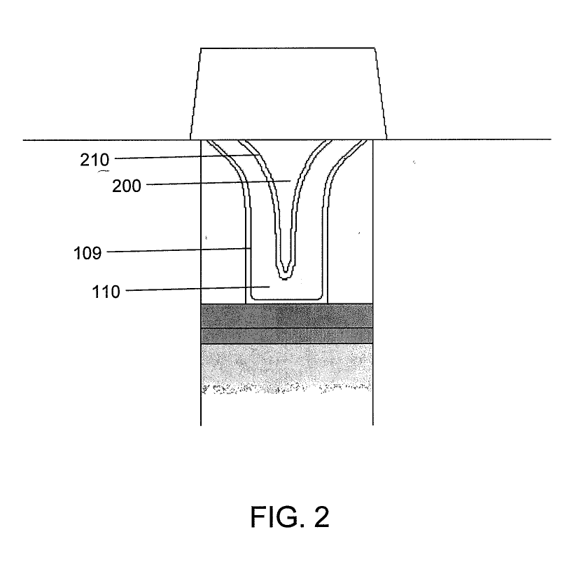

In another embodiment of the present invention, as depicted in FIG. 2, the deposition of the PCM material is separated into two depositions 110, 200 with a second breakdown layer 210 deposited in between. This enables the formation of an even thinner first deposited layer of PCM material to further constrain the volume of PCM material to be heated. This approach will help to further constrain the volume of PCM material and give more control over the heating and cooling of the PCM material.

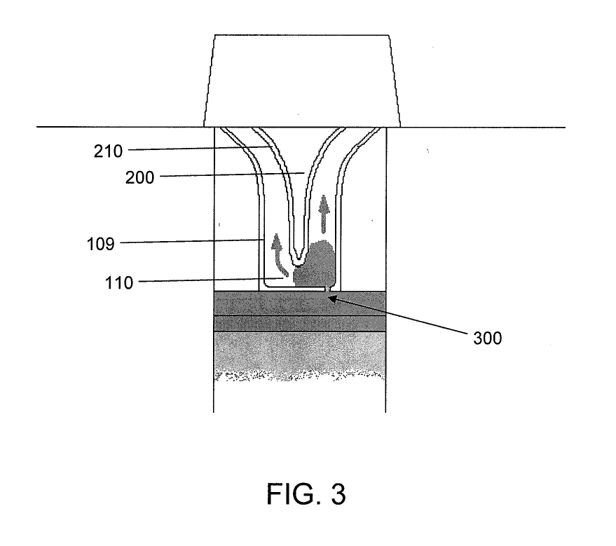

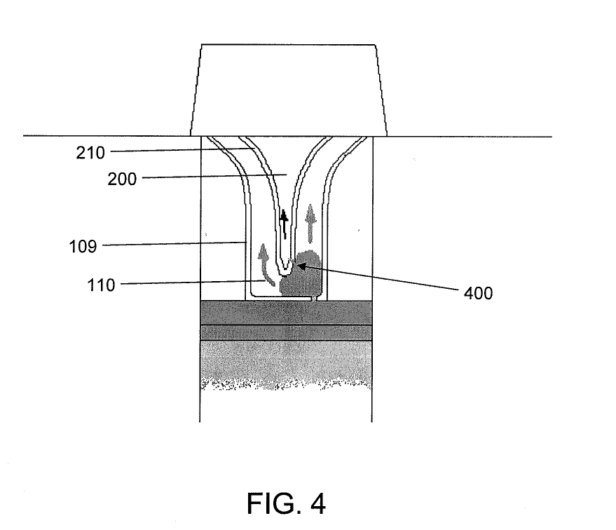

Activation of the PCM memory cell depicted in FIG. 1 may be accomplished by applying a voltage (e.g., in the forward voltage direction of the diode) across the top and bottom contacts such that the breakdown layer 109 is breached (as is done with an antifuse and is known to those skilled in the art), thereby forming a filament and very small contact point to the bottom of the GST material. Activation of the PCM memory cell depicted in FIGS. 2 through 4 may be accomplished by applying a voltage (in the forward voltage direction of the diode) across the top and bottom contacts such that the dielectric layers are breached in stages. In the first stage, as depicted in FIG. 3, the current path may be along the sidewalls of the cup through the thin, first deposited PCM layer 110; this current may cause a breach (as is done with an antifuse and is known to those skilled in the art) through the lower breakdown layer 109, thereby forming a filament 300 (and, hence, a very small contact point to the bottom of the GST material). The PCM material may be heated and melted in the vicinity of the breach and the current may be ramped down such that an area of low resistance is formed in the PCM material at that area. In the second stage, as depicted in FIG. 4, a second voltage may be applied to create a current path through the core PCM layer 200 (the “core”), causing a breach 400 to be formed through the second breakdown layer 210 to the area of low resistance PCM material of the first PCM layer 110. The core PCM material 200 will be heated and melt in the vicinity of the breach of the second deposited breakdown layer and the current will be ramped down such that an area of low resistance is formed in the core PCM material 200 at that area. A variation on this latter structure may include making the core out of a material other than PCM material 200 to vary the amount of cooling following melting, but still resulting in a very small volume of PCM material that will be melted during programming or erasing the storage element PCM between the two breakdown layer breaches.

Memory devices incorporating embodiments of the present invention may be applied to memory devices and systems for storing digital text, digital books, digital music (such as MP3 players and cellular telephones), digital audio, digital photographs (wherein one or more digital still images may be stored including sequences of digital images), digital video (such as personal entertainment devices), digital cartography (wherein one or more digital maps can be stored, such as GPS devices), and any other digital or digitized information as well as any combinations thereof. Devices incorporating embodiments of the present invention may be embedded or removable, and may be interchangeable among other devices that can access the data therein. Embodiments of the invention may be packaged in any variety of industry-standard form factor, including Compact Flash, Secure Digital, MultiMedia Cards, PCMCIA Cards, Memory Stick, any of a large variety of integrated circuit packages including Ball Grid Arrays, Dual In-Line Packages (DIPs), SOICs, PLCC, TQFPs and the like, as well as in proprietary form factors and custom designed packages. These packages may contain just the memory chip, multiple memory chips, one or more memory chips along with other logic devices or other storage devices such as PLDs, PLAs, micro-controllers, microprocessors, controller chips or chip-sets or other custom or standard circuitry.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A memory cell comprising:
a current-steering device;
a phase-change material disposed over the current-steering device; and
disposed between the current-steering device and the phase-change material, an element for increasing heat transfer to the phase-change material upon application of a voltage to the memory cell.

2. The memory cell of claim 1, wherein the element comprises a layer having a resistance larger than a resistance of at least a portion of the current-steering device.

3. The memory cell of claim 1, wherein the element comprises an implanted elemental species selected from the group consisting of: oxygen, nitrogen, and germanium.

4. The memory cell of claim 1, wherein the current-steering device comprises a diode.

5. The memory cell of claim 1, wherein the phase-change material comprises an alloy of germanium, antimony, and tellurium.

6. A method of forming a memory cell, the method comprising:
providing a current-steering device;
providing a phase-change material over the current-steering device; and
providing, between the current-steering device and the phase-change material, an element for increasing heat transfer to the phase-change material upon application of a voltage to the memory cell.

7. The method of claim 6, wherein the element is provided by ion implantation of at least one elemental species.

8. The method of claim 7, wherein the at least one elemental species comprises at least one of oxygen, nitrogen, or germanium.

9. A memory cell comprising:
a current-steering device;
a cooling element disposed over the current-steering device; and
a phase-change material disposed over the current-steering device and around at least a portion of the cooling element.

10. The memory cell of claim 9, wherein the cooling element comprises a material having a higher thermal conductivity than a thermal conductivity of the phase-change material.

11. The memory cell of claim 9, wherein the cooling element comprises a non-phase-change material.

12. The memory cell of claim 11, wherein the cooling element comprises tungsten.

13. The memory cell of claim 11, wherein the cooling element comprises diamond.

14. A method of forming a memory cell, the method comprising:
providing a current-steering device;
providing over the current-steering device a volume of phase-change material disposed around a core region; and
providing a cooling element within the core region.

15. The method of claim 14, wherein the cooling element comprises a material having a higher thermal conductivity than a thermal conductivity of the phase-change material.

16. The method of claim 14, wherein the cooling element comprises a non-phase-change material.

17. The method of claim 16, wherein the cooling element comprises tungsten.

18. The method of claim 16, wherein the cooling element comprises diamond.

19. A memory cell comprising:
a current-steering device;
a first phase-change material disposed over the current-steering device;
a first breakdown layer disposed between the current-steering device and the first phase-change material;
a second phase-change material disposed over the first phase-change material; and
a second breakdown layer disposed between the first phase-change material and the second phase-change material.

20. The memory cell of claim 19, wherein the first and second breakdown layers each comprise a dielectric material.

21. The memory cell of claim 19, wherein the first and second breakdown layers each comprise a breach therethrough.

22. The memory cell of claim 19, wherein the first and second phase-change materials are different.

23. A method of forming a memory cell, the method comprising:
providing a current-steering device;
providing a first phase-change material over the current-steering device;
providing a first breakdown layer between the current-steering device and the first phase-change material;
providing a second phase-change material over the first phase-change material; and
providing a second breakdown layer between the first phase-change material and the second phase-change material.

24. The method of claim 23, further comprising forming a first breach in the first breakdown layer by applying a voltage across the first breakdown layer.

25. The method of claim 24, further comprising forming a second breach in the second breakdown layer by applying a voltage across the second breakdown layer.
